(19) United States
(12) Patent Application Publication
(10) Pub. No.: US 2026/0334131 A1
(43) Pub. Date: Oct. 22, 2026

(54) SUBSTRATE CLEANING APPARATUS AND SUBSTRATE TREATMENT SYSTEM INCLUDING THE SAME

(71) Applicant: Samsung Electronics Co., Ltd., Suwon-si (KR)

(72) Inventors: Sang Jine PARK, Suwon-si, Gyeonggi-do (KR); Ji Hwan PARK, Suwon-si, Gyeonggi-do (KR)

(21) Appl. No.: 19/565,447

(22) Filed: Mar. 12, 2026

(30) Foreign Application Priority Data
Mar. 27, 2025 (KR) 10-2025-0039528

(51) Int. Cl. H10P 72/00; H10P 72/30

(52) U.S. Cl. CPC H10P 72/0414; H10P 72/3306

(57) ABSTRACT

A substrate cleaning apparatus includes a substrate holder configured to support a substrate, a spin pillar connected to the substrate holder and configured to rotate the substrate, and a cleaning liquid supply configured to spray a cleaning liquid onto a surface of the substrate. The cleaning liquid supply includes (i) a nozzle arm having one end rotating along a sweep trajectory over the surface of the substrate and (ii) a nozzle coupled to the one end of the nozzle arm and configured to spray the cleaning liquid along a target trajectory on the surface of the substrate. The sweep trajectory includes sweep points and the target trajectory includes target points corresponding to and overlapping the sweep points in vertical direction. While the nozzle passes through each sweep point, spraying direction of the nozzle coincides with rotational direction of the target point corresponding to each sweep point in a plan view.

### CROSS-REFERENCE TO RELATED APPLICATION

This application claims priority to Korean Patent Application No. 10-2025-0039528 filed on Mar. 27, 2025 in the Korean Intellectual Property Office, and all the benefits accruing therefrom under 35 U.S.C. 119, the contents of which in its entirety are herein incorporated by reference.

### BACKGROUND

In semiconductor device manufacturing, maintaining surface integrity may be desired to ensure optimal performance. As fabrication processes become increasingly complex, specialized equipment may be needed to support precise and contamination-free operations.

### SUMMARY

When the substrate is treated through an etching process to form a circuit pattern on the substrate, process by-products such as particles or organic materials may remain on a surface of the substrate. In this case, in order to remove the process by-products on the substrate, the substrate may be cleaned using substrate cleaning apparatus. However, in the cleaning process, when a direction in which the substrate rotates and a direction in which cleaning liquid is sprayed from a nozzle are different from each other, the cleaning liquid may splash into the substrate cleaning apparatus. This may contaminate an inside of the substrate cleaning apparatus.

Implementations according to the present disclosure provides a substrate cleaning apparatus that minimizes splashing of cleaning liquid during a cleaning process of a substrate.

Implementations according to the present disclosure provides a substrate treating system including a substrate cleaning apparatus that minimizes splashing of cleaning liquid during a cleaning process of a substrate.

An aspect of the present disclosure provides a substrate cleaning apparatus including a substrate holder constructed to support a substrate, a spin pillar connected to the substrate holder and configured to rotate the substrate, and a cleaning liquid supply structure configured to spray a cleaning liquid onto a surface of the substrate, wherein the cleaning liquid supply structure includes, a nozzle arm having one end rotating along a sweep trajectory over the surface of the substrate, and a nozzle coupled to the one end of the nozzle arm and spraying the cleaning liquid along a target trajectory on the surface of the substrate, wherein the sweep trajectory includes a plurality of sweep points, wherein the target trajectory includes a plurality of target points corresponding to and overlapping the plurality of sweep points in a vertical direction, wherein while the nozzle passes through each of the plurality of sweep points, a spraying direction of the nozzle coincides with a rotation direction of the target point corresponding to each sweep point in a plan view of the apparatus.

Another aspect of the present disclosure provides a substrate cleaning apparatus including, a housing, a substrate holder disposed in the housing and configured to support a substrate, a spin pillar connected to the substrate holder and configured to rotate the substrate, a door installed on a side wall of the housing, wherein the substrate is input into or withdrawn out of the housing through the door, a fan filter unit installed on an upper surface of the housing and configured to control an airflow inside the housing, a cleaning liquid supply structure configured to spray a cleaning liquid onto a surface of the substrate, and a controller configured to control each of the cleaning liquid supply structure and the spin pillar, wherein the cleaning liquid supply structure includes, an arm pillar extending in a parallel manner to a central axis of the substrate, and a nozzle arm having one end connected to the arm pillar and the other end rotating along a sweep trajectory over the surface of the substrate, and a nozzle coupled to the other end of the nozzle arm and spraying the cleaning liquid along a target trajectory on the surface of the substrate, wherein the controller is configured to control a spraying direction of the nozzle to continuously vary while the nozzle travels along the sweep trajectory.

Another aspect of the present disclosure provides a substrate treating system for treating a substrate, the system including, a process-treating module for processing the substrate, and a substrate cleaning apparatus for cleaning the substrate after the process-treating module has processed the substrate, wherein the substrate cleaning apparatus includes, a substrate holder constructed to support the substrate, a spin pillar connected to the substrate holder and configured to rotate the substrate, and a cleaning liquid supply structure configured to spray a cleaning liquid onto a surface of the substrate, wherein the cleaning liquid supply structure includes, a nozzle arm having one end rotating along a sweep trajectory over the surface of the substrate, and a nozzle coupled to the one end of the nozzle arm and spraying the cleaning liquid along a target trajectory on the surface of the substrate, wherein the sweep trajectory includes a plurality of sweep points, wherein the target trajectory includes a plurality of target points corresponding to and overlapping the plurality of sweep points in a vertical direction, wherein while the nozzle passes through each of the plurality of sweep points, a spraying direction of the nozzle coincides with a rotation direction of the target point corresponding to each sweep point in a plan view of the apparatus.

Specific details of other implementations are included in the detailed description and drawings.

### BRIEF DESCRIPTION OF DRAWINGS

FIG. 1 is a schematic plan view of an example of a substrate treating system including an example of a substrate cleaning apparatus.

FIG. 2 is a cross-sectional view schematically illustrating an internal structure of an example of a substrate cleaning apparatus.

FIG. 3 is a perspective view for illustrating an example of a nozzle.

FIG. 4 is a plan view illustrating an example of a rotation of a nozzle arm on a substrate.

FIG. 5 is a schematic perspective view for illustrating an example of a rotation of a nozzle arm on a substrate.

FIGS. 6 and 7 are schematic plan views for illustrating an example of nozzle spraying a cleaning liquid onto a substrate.

FIG. 8 is a graph illustrating an example of an angle defined between a nozzle arm and a cleaning liquid spray direction from a nozzle based on a position of the nozzle.

FIG. 9 is a plan view illustrating an example of a rotation of a nozzle arm on a substrate.

FIG. 10 is a schematic perspective view for illustrating an example of a rotation of a nozzle arm on a substrate.

FIGS. 11 and 12 are schematic plan views for illustrating an example of nozzle spraying a cleaning liquid onto a substrate.

FIG. 13 is a graph illustrating an example of an angle defined between a nozzle arm and a cleaning liquid spray direction of a nozzle based on a position of the nozzle.

FIG. 14 is a plan view for illustrating an example of a rotation of a nozzle arm on a substrate.

FIG. 15 is a perspective view for illustrating an example of a nozzle.

### DETAILED DESCRIPTION

Hereinafter, implementations of the present disclosure will be described in detail with reference to the accompanying drawings. The same reference numerals are used for the same components in the drawings, and redundant descriptions thereof will be omitted.

In the present disclosure, although first, second, upper, and lower are used to describe various elements or components, these elements or components are not limited by these terms. These terms are merely used to distinguish one element or component from another. Accordingly, it is obvious that the first element or component mentioned below may be the second element or component within the technical idea of the present disclosure. Further, it is obvious that a lower element or component mentioned below may be an upper element or component within the technical spirit of the present disclosure.

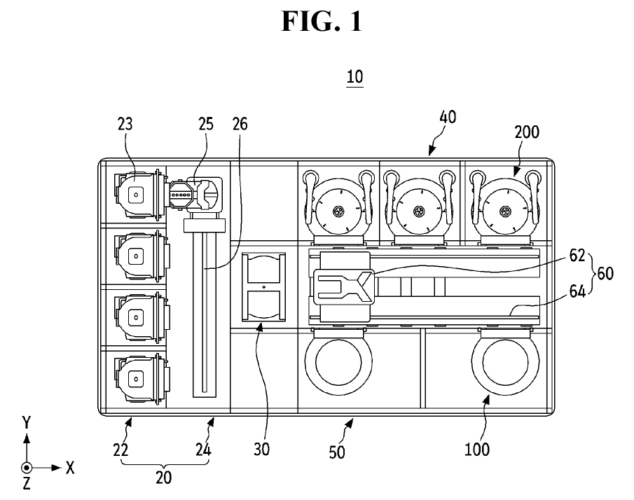

Hereinafter, a substrate treating system according to some implementations of the present disclosure will be described with reference to FIG. 1.

FIG. 1 is a schematic plan view of a substrate treating system including a substrate cleaning apparatus according to some implementations of the present disclosure;

Referring to FIG. 1, a substrate treating system 10 according to some implementations may include an index module 20, a buffer module 30, a first process-treating module 40, a second process-treating module 50, and a transfer module 60.

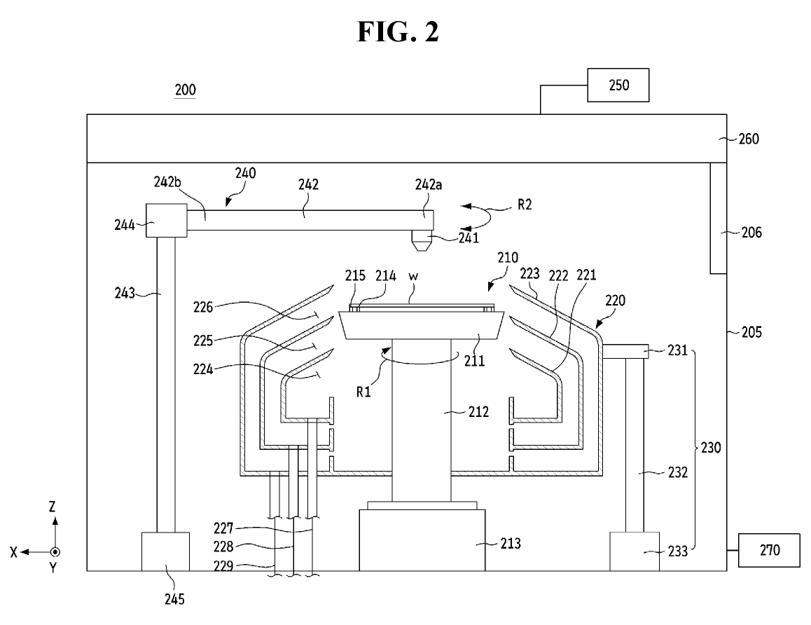

For example, the index module 20 may load and unload substrates such as wafers (see W in FIG. 2). The buffer module 30 may be disposed on one side of the index module 20 (e.g., one side thereof in the first direction X). The substrates may be transferred to the first process-treating module 40 and the second process-treating module 50 via the buffer module 30. Thus, the first process-treating module 40 and the second process-treating module 50 may sequentially perform processes on the substrates W.

The index module 20 may include a load port 22 and an index frame 24. The load port 22 is a component into or from which the substrate W is loaded or unloaded, and a plurality of support plates may be disposed in the load port 22 and may be arranged along the second direction Y. A front opening unified pod (FOUP) 23 in which a plurality of substrates W are accommodated may be seated on the support plate. An indexer robot 25 may be movable along a guide rail 26 extending in the second direction Y, and may transfer the substrate W between a wafer carrier 23 on the load port 22 and the buffer module 30.

The buffer module 30 may be disposed on one side of the index frame 24. The transfer module 60 may extend from the buffer module 30 in the first direction X. The first process-treating module 40 may be disposed on one side in the second direction Y of the transfer module 60. The second process-treating module 50 may be disposed on the other side in the second direction Y of the transfer module 60. The first process-treating module 40 may extend along the first direction X. The second process-treating module 50 may extend along the first direction X.

For reference, the first direction X and the second direction Y may intersect each other. In addition, a third direction Z of FIG. 2 may intersect a plane defined by the first direction X and the second direction Y. For example, as used herein, "vertical direction" may mean the third direction Z.

The buffer module 30 may provide a space in which each of the substrate W transferred from the index frame 22 to the first process-treating module 40 and the substrate W transferred from the second process-treating module 50 to the index frame 22 temporarily stays. Alternatively, the buffer module 30 may provide a space in which each of the substrate W transferred from the index frame 22 to the second process-treating module 50 and the substrate W transferred from the first process-treating module 40 to the index frame 22 temporarily stays.

The first process-treating module 40 and the second process-treating module 50 may treat the substrate W. Each of the first process-treating module 40 and the second process-treating module 50 may be embodied as a plurality of process chambers. The plurality of process chambers may be arranged to surround the transfer module 60. Each of the plurality of process chambers may be provided in a cylindrical shape or a polygonal shape.

For example, the first process-treating module 40 may include a plurality of first process chambers 200, and the second process-treating module 50 may include a plurality of second process chambers 100. The plurality of first process chambers 200 may be chambers that perform the same type of processes.

In some implementations of the present disclosure, the first process-treating module 40 and the second process-treating module 50 may be configured to sequentially perform processes on one substrate W. For example, the first process-treating module 40 may perform a cleaning process on the substrate W, and then, the second process-treating module 50 may perform a drying process thereon. The cleaning process may include sequentially performing a chemical process, a rinse process, and a substitution process on the substrate W. The drying process may be performed using a supercritical fluid. For example, the first process chamber 200 may be substrate cleaning apparatus.

In some implementations of the present disclosure, the second process-treating module 50 and the first process-treating module 40 may be configured to sequentially perform processes on one substrate W. For example, the second process-treating module 50 may perform an etching process on the substrate W. Thereafter, a cleaning process thereon may be performed in the first process-treating module 40. The etching process may be, for example, a chemical mechanical planarization (CMP) process.

A transfer module 60 for transferring the substrate W may be disposed between the first process-treating module 40 and the second process-treating module 50. A transfer robot 62 may transfer the substrate W while moving along a transfer rail 64 extending along the first direction X. The transfer robot 62 may transfer the substrate W disposed on the buffer module 30 to the first process-treating module 40 or the second process-treating module 50. The transfer robot 62 may transfer the substrate W between the first process-treating module 40 and the second process-treating module 50. For example, the substrate W on which the cleaning process has been performed in the first process-treating module 40 may be transferred to the second process-treating module 50. In addition, for example, the substrate W on which the etching process has been performed in the second process-treating module 50 may be transferred to the first process-treating module 40. The transfer robot 62 may transfer the substrate W which has been treated in the first process-treating module 40 or the second process-treating module 50 to the buffer module 30.

Although not shown in FIG. 1, the substrate treating system 10 may further include a control device for controlling the substrate treating system 10. The control device may serve to control the overall operation of each of the modules constituting the substrate treating system 10. For example, the control device may be configured to control the process treatment on the substrate W of each of the first process treatment module 40 and the second process treatment module 50.

Hereinafter, substrate cleaning apparatus according to some implementations of the present disclosure will be described with reference to FIGS. 2-15. For reference, the substrate cleaning apparatus may be embodied as the first process chamber 200 described in FIG. 1.

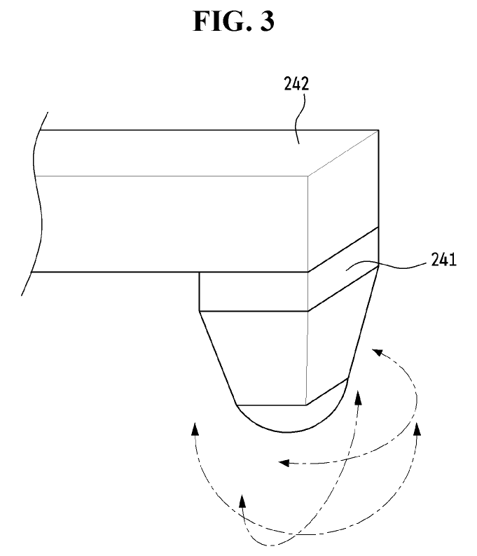

FIG. 2 is a cross-sectional view schematically illustrating an internal structure of the substrate cleaning apparatus according to some implementations of the present disclosure. FIG. 3 is a perspective view for illustrating a nozzle according to some implementations of the present disclosure. Contents duplicate with or similar to those as described with reference to FIG. 1 will be briefly described or the descriptions thereof are omitted.

Referring to FIGS. 2 and 3, the substrate cleaning apparatus 200 may include a housing 205, a door 206, a substrate support unit 210, a cleaning liquid collection unit 220, a vertically-moving unit 230, a cleaning liquid supply structure 240, a pressing unit 250, a fan filter unit 260, and a controller 270.

The housing 205 of the substrate cleaning apparatus 200 may constitute an outer wall of the substrate cleaning apparatus 200. The housing 205 is shown in a rectangular parallelepiped or cylindrical shape, but this is merely an example. The substrate support unit 210, the cleaning liquid collection unit 220, the vertically-moving unit 230, the cleaning liquid supply structure 240, and the fan filter unit 260 may be disposed in the housing 205.

The door 206 may be installed on the housing 205. The door 206 may be installed inside the housing 205 as shown. In some implementations, the door 206 may be installed on an outer wall of the housing 205. Through the door 206, the substrate W may be input into or be withdrawn out of the housing 205. That is, the substrate W may move between the substrate cleaning apparatus 200 and an external transfer module (e.g., 60 of FIG. 1) through the door 206.

The substrate support unit 210 supports the substrate W thereon while the treatment module is treating the substrate W. The substrate support unit 210 may include a substrate holder 211, a spin pillar 212, and a spin driver 213.

The substrate holder 211 may be constructed to support the substrate W thereon. The substrate holder 211 may extend in each of the first direction X and the second direction Y. The substrate holder 211 may have, for example, a shape of a plate. In some implementations, the substrate holder 211 may be connected to the spin pillar 212 to be described later and spin. The substrate holder 211 may rotate (spin) in a R1 direction, for example, in a clockwise direction or a counterclockwise direction. The substrate holder 211 may rotate the substrate W seated thereon.

In some implementations of the present disclosure, the substrate holder 211 may include a support pin 214 and a guide pin 215. The support pin 214 may support a lower surface of the substrate W. The support pin 214 may support the substrate W such that the substate is spaced apart from a upper surface of the substrate holder 211. The guide pin 215 may support a side surface of the substrate W. The guide pin 215 may prevent the rotating substrate W from being removed from the substrate holder 211. The guide pin 215 may function as a chucking pin. A plurality of support pins 214 and a plurality of guide pins 215 may be disposed on a surface of the substrate holder 211. The support pins 214 may be arranged in an annular ring shape. The guide pins 215 may be arranged in an annular ring shape.

The spin pillar 212 may be disposed under the substrate holder 211. The spin pillar 212 may be connected to the substrate holder 211. The spin pillar 212 may extend in the third direction Z. The spin pillar 212 may convert electrical energy provided from the spin driver 213 into kinetic energy to rotate the substrate holder 211 in the R1 direction. That is, the spin pillar 212 may consequently rotate the substrate W in the R1 direction. The spin pillar 212 may be installed on the spin driver 213, and the substrate holder 211 may be rotatably coupled on the spin pillar 212.

The cleaning liquid collection unit 220 collects the cleaning liquid used to clean the substrate W. The cleaning liquid collection unit 220 may be constructed to surround the substrate support unit 210. The cleaning liquid collection unit 220 may provide a space in which a substrate cleaning process is performed.

The cleaning liquid collection unit 220 may include a single or a plurality of collection barrels. For example, the cleaning liquid collection unit 220 may include three collection containers 221, 222, and 223, such as a first collection container 221, a second collection container 222, and a third collection container 223. The cleaning liquid collection unit 220 may collect the cleaning liquid of the substrate W in a separate manner using the plurality of collection containers such that the apparatus can recycle the cleaning liquid of the substrate W. The cleaning liquid collection unit 220 may be embodied as a bowl.

In some implementations of the present disclosure, the first collection container 221, the second collection container 222, and the third collection container 223 may collect the cleaning liquids having different types of the substrate W, respectively. For example, the first collection container 221 may collect the rinse liquid through a first inlet 224. In addition, for example, the second collection container 222 may collect a first chemical solution through a second inlet 225. In addition, for example, the third collection container 223 may collect a second chemical solution through a third inlet 226. The rinse liquid may be, for example, de-ionized water (DIW), and the first chemical solution or the second chemical solution may be IPA.

Although not shown in FIG. 2, the first collection container 221, the second collection container 222, and the third collection container 223 may be connected to a cleaning liquid regeneration device via a first collection line 227, a second collection line 228, and a third collection line 229. The cleaning liquid regeneration device may treat the cleaning liquid of the substrate W so as to be reusable.

Each of the first collection container 221, the second collection container 222, and the third collection container 223 may extend in an annular ring shape. The first collection container 221 may be constructed to surround the substrate support unit 210, the second collection container 222 may be constructed to surround the first collection container 221, and the third collection container 223 may be constructed to surround the second collection container 222. A spacing between the first collection container 221 and the second collection container 222 may be equal to a spacing between the second collection container 222 and the third collection container 223.

The vertically-moving unit 230 may include a bracket 231, a vertically-movable shaft 232, and a vertical-motion driver 233. The bracket 231 may be coupled to the outer wall of the cleaning liquid collection unit 220. The vertically-movable shaft 232 may convert electrical energy provided from the vertical-motion driver 233 into kinetic energy to vertically move the bracket 231. The cleaning liquid collection unit 220 may vertically move in conjunction with the bracket 231.

The vertically-moving unit 230 may adjust a vertical level of the cleaning liquid collecting unit 220. When the substrate W is seated on the substrate holder 211, the vertically-moving unit 230 may position the third collection container 223 at a lower level than a vertical level of the substrate holder 211. Even when the substrate W is detached from the substrate holder 211, the vertically-moving unit 230 may position the third collection container 223 at a lower level than a vertical level of the substrate holder 211. When the rinsing liquid is collected, the vertically-moving unit 230 may position the first inlet 224 at the same level as a vertical level of the substrate W in the third direction Z. When the first chemical solution is collected, the vertically-moving unit 230 may position the second inlet 225 at the same level as that of the substrate W in the third direction Z. When the second chemical solution is collected, the vertically-moving unit 230 may position the third inlet 226 at the same level as that of the substrate W in the third direction Z.

The cleaning liquid supply structure 240 may be configured to spray the cleaning liquid onto a surface of the substrate W. In this regard, the surface of the substrate W may mean a surface of the substrate W facing the cleaning liquid supply structure 240. The cleaning liquid supply structure 240 may include a nozzle 241, a nozzle arm 242, an arm pillar 243, a rotation driver 244, and an arm vertical-motion driver 245.

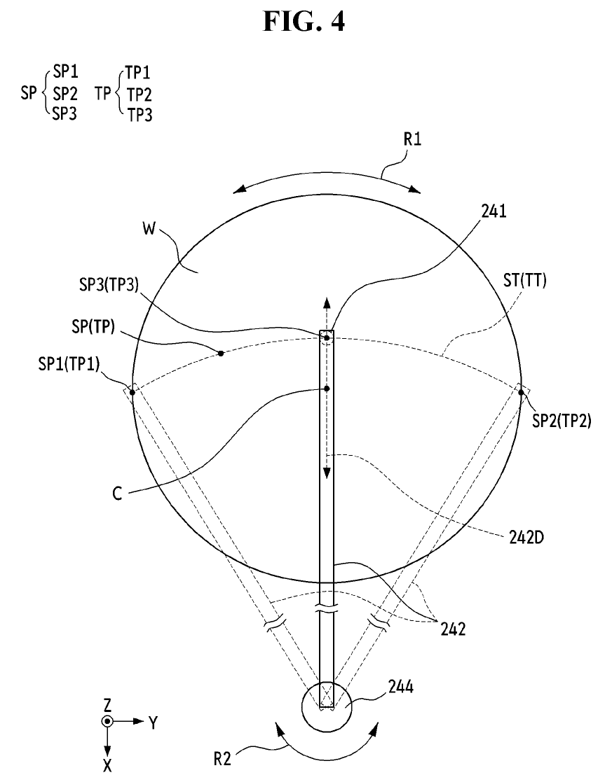

The arm pillar 243 may be disposed to be spaced apart from the substrate support unit 210 in the horizontal direction. For example, the arm pillar 243 may be spaced apart from the substrate support unit 210 in each of the first direction X and the second direction Y. The arm pillar 243 may extend in the third direction Z. The arm pillar 243 may extend parallel to a central axis of the substrate W (for example, see C of FIG. 4). A lower end of the arm pillar 243 may be connected to the arm vertical-motion driver 245. An upper end of the arm pillar 243 may be connected to the rotation driver 244.

In some implementations of the present disclosure, the arm vertical-motion driver 245 may move up or down the arm pillar 243, the nozzle arm 242, and the nozzle 241 in the third direction Z. The arm pillar 243 may convert the electrical energy received from the arm vertical-motion driver 245 into kinetic energy and thus be movable in the third direction Z. For example, the arm vertical-motion driver 245 may move the nozzle 241 to a process position or a standby position.

In addition, in some implementations of the present disclosure, the rotation driver 244 may rotate the nozzle arm 242 and the nozzle 241 in a R2 direction (e.g., meaning a clockwise direction or a counterclockwise direction on a horizontal plane intersecting the third direction Z). The nozzle arm 242 may convert the electrical energy received from the rotation driver 244 into kinetic energy and thus rotate in the R2 direction. For example, the nozzle 241 may rotate along a sweep trajectory (see ST of FIG. 4) to be described later through the rotation driver 244.

In some implementations of the present disclosure, the roles of the arm vertical-motion driver 245 and the rotation driver 244 may be different from those in the above description. For example, the arm vertical-motion driver 245 may not only raise or lower the arm pillar 243, the nozzle arm 242, and the nozzle 241 in the third direction Z, but also rotate the nozzle arm 242 and the nozzle 241 in the R2 direction. In this case, the rotation driver 244 may transmit the rotational kinetic energy received through the arm vertical-motion driver 245 and the arm pillar 243 to the nozzle arm 242 and the nozzle 241.

The nozzle arm 242 may extend in one direction (e.g., see 242D of FIG. 4) as the horizontal direction. The nozzle arm 242 may have an elongated cylindrical shape extending in one direction. Both opposing ends of the nozzle arm 242 may be referred to as a first end 242a and a second end 242b. The nozzle 241 which will be described later may be connected to the first end 242a of the nozzle arm 242. The arm pillar 243 may be connected to the second end 242b of the nozzle arm 242. For example, the rotation driver 244 may contact the second end 242b of the nozzle arm 242, and the nozzle arm 242 may be connected to the arm pillar 243 with the rotation driver 244 interposed therebetween.

In some implementations of the present disclosure, the first end 242a of the nozzle arm 242 may rotate along the sweep trajectory ST. In addition, the nozzle 241 coupled to the first end 242a of the nozzle arm 242 may also move along the sweep trajectory ST. This will be described later.

The nozzle 241 may spray the cleaning liquid along a target trajectory (e.g., see TT of FIG. 4) on the surface of the substrate W. The nozzle 241 may be coupled to the first end 242a of the nozzle arm 242. The nozzle 241 may rotate along the sweep trajectory ST as the nozzle arm 242 rotates in the R2 direction. For example, the nozzle 241 may move along the sweep trajectory ST, and may spray the cleaning liquid onto the target trajectory TT on the surface of the substrate W. This will be described later.

In some implementations of the present disclosure, the cleaning liquid may be a liquid substance (e.g., an organic solvent) or a gaseous substance. The cleaning liquid may include a substance which has high volatility, and produces a large amount of fume and has high persistence due to high viscosity. For example, the cleaning liquid may be embodied as a substance including an iso-propyl alcohol (IPA) component, a substance including a sulfuric acid component, a substance including an ammonia water component, a substance including a hydrofluoric acid component, a substance including a phosphoric acid component, or the like. For example, the substance including a sulfuric acid component may be embodied as SPM. For example, the substance including an ammonia water component may be embodied as SC-1 (H₂O₂+NH₄OH). For example, the substance including a hydrofluoric acid component may be embodied as a Distributed Hydrogen Fluoride (DHF).

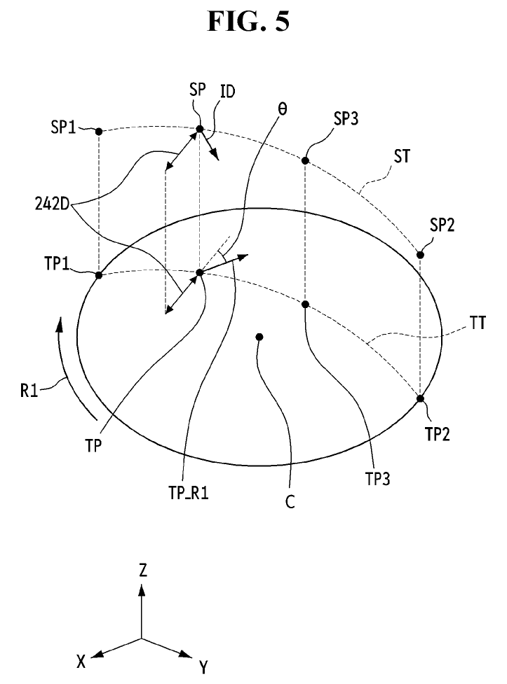

In FIG. 3, the nozzle 241 may protrude in the third direction Z from the first end 242a of the nozzle arm 242. The nozzle 241 may protrude from the first end 242a of the nozzle arm 242 toward the substrate W in the third direction Z. The nozzle 241 may be coupled to the nozzle arm 242 so as to rotate in various directions with respect to the nozzle arm 242. In some implementations of the present disclosure, the nozzle 241 may rotate in various directions with respect to the nozzle arm 242 to adjust a cleaning liquid spraying direction (e.g., see ID of FIG. 5) of the nozzle 241 to be described later. That is, the nozzle 241 rotates in various directions with respect to the nozzle arm 242, and the cleaning liquid spraying direction ID of the nozzle 241 may be adjusted to coincide with a rotation direction of the target point on the surface of the substrate W in a plan view. For reference, as used herein, the term "plan view" may mean a viewpoint viewed in the third direction Z.

The pressing unit 250 may be installed outside the housing 205. The pressing unit 250 may transmit pressure to the inside of the housing 205. For example, the pressing unit 250 may allow the pressure inside the housing 205 to be maintained at a higher level than the pressure outside the housing 205. For example, the substrate cleaning apparatus 200 may maintain a high pressure sealing environment inside the housing 205.

The fan filter unit 260 may be installed inside the housing 205. The fan filter unit 260 may be installed on an upper portion of a side wall of the housing 205. The fan filter unit 260 may include a fan to adjust the airflow inside the housing 205. For example, the fan filter unit 260 may introduce air outside the housing 205 into the housing 205 through the fan. In addition, the fan filter unit 260 may include a filter to remove contaminants that may be introduced together with the air outside the housing 205. For example, the filter may include a high efficiency particulate air (HEPA) filter or a ultra-low penetration air (ULPA) filter.

In some implementations of the present disclosure, the controller 270 is shown as being installed outside the housing 205. The controller 270 may be configured to control the cleaning liquid supply structure 240 and the substrate support unit 210. The controller 270 may be electrically connected to the cleaning liquid supply structure 240 and the substrate support unit 210 and may be configured to control the cleaning liquid supply structure 240 and the substrate support unit 210. In some implementations, the controller 270 may be configured to control the cleaning liquid supply structure 240 and the substrate support unit 210 in a wireless communication manner.

For example, the controller 270 may be configured to control the cleaning liquid supply structure 240 to spray the cleaning liquid onto the surface of the substrate W. The controller 270 may be configured to control the cleaning liquid spray direction ID of the nozzle 241 to coincide with a rotation direction TP_R1 of the target point (see TP of FIG. 5) to which the cleaning liquid is to be sprayed in a plan view. That is, the controller 270 may be configured to control the nozzle 241 to rotate in various directions with respect to the nozzle arm 242.

In another example, the controller 270 may be configured to control the nozzle arm 242 to rotate along the sweep trajectory ST on the surface of the substrate W. The controller 270 may be configured to control the nozzle arm 242 to reciprocate and rotate along the sweep trajectory ST until the surface of the substrate W is sufficiently cleaned.

In still another example, the controller 270 may be configured to control the spin pillar 212 of the substrate support unit 210 to spin. The controller 270 may be configured to control the spin driver 213 to transmit kinetic energy to the spin pillar 212 so as to rotate in the R1 direction.

Hereinafter, in some implementations of the present disclosure, an operation in which while the nozzle arm 242 rotates on the surface of the substrate W, the nozzle 241 sprays the cleaning liquid onto the surface of the substrate W.

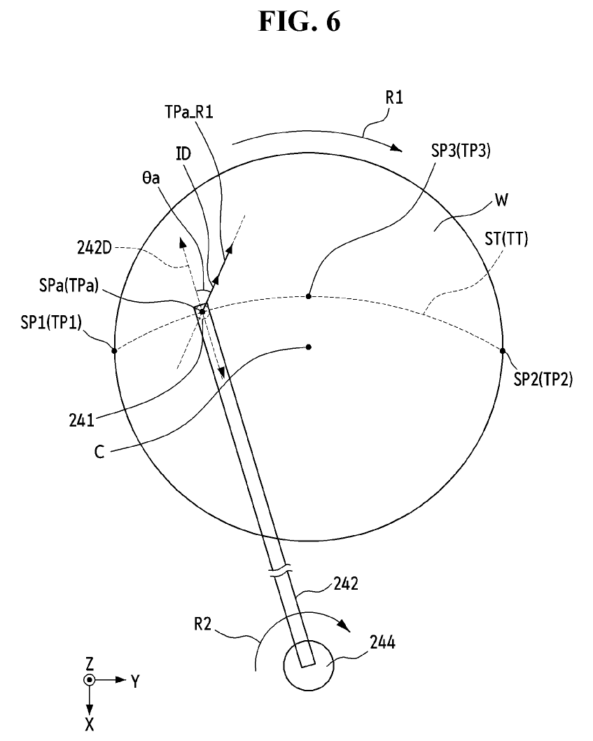

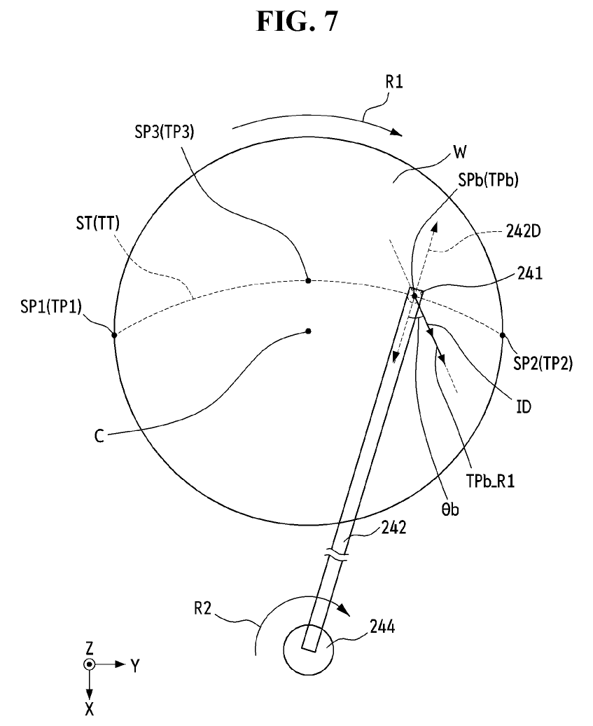

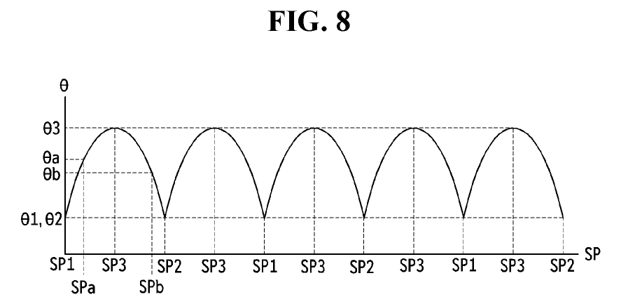

FIG. 4 is a plan view for illustrating that a nozzle arm rotates on a substrate according to some implementations of the present disclosure. FIG. 5 is a schematic perspective view for illustrating that the nozzle arm rotates on a substrate according to some implementations of the present disclosure. FIGS. 6 and 7 are schematic plan views for illustrating that the nozzle sprays a cleaning liquid onto a substrate according to some implementations of the present disclosure. FIG. 8 is a graph illustrating an angle defined between a nozzle arm and a cleaning liquid spray direction from a nozzle based on a position of the nozzle according to some implementations of the present disclosure. Contents duplicate with or similar to those described above with reference to FIGS. 1 to 3 will be briefly described or the descriptions thereof are omitted.

Referring to FIGS. 4 and 5, the first end (see 242a of FIG. 2) of the nozzle arm 242 may rotate along the sweep trajectory ST.

In some implementations of the present disclosure, the sweep trajectory ST may be spaced apart from the substrate W in the third direction Z. The sweep trajectory ST may draw an arc in a plan view. The arc of the sweep trajectory ST may mean an arc on the circular surface of the substrate W in a plan view. The sweep trajectory ST may include a plurality of sweep points SP. For example, a first sweep point SP1 and a second sweep point SP2 may mean both opposing end points of the arc of the sweep trajectory ST. In addition, for example, a third sweep point SP3 may mean a center of the arc of the sweep trajectory ST. That is, a distance from the first sweep point SP1 to the third sweep point SP3 may be equal to a distance from the second sweep point SP2 to the third sweep point SP3.

In some implementations of the present disclosure, the first end 242a of the nozzle arm 242 and the nozzle 241 may rotate in the R2 direction along the sweep trajectory ST, and accordingly, the first end 242a of the nozzle arm 242 and the nozzle 241 may reciprocate in a single round passing through the first sweep point SP1, the third sweep point SP3, the second sweep point SP2, the third sweep point SP3, and the first sweep point SP1. However, this is merely an example, and in some other implementations of the present disclosure, the first end 242a of the nozzle arm 242 and the nozzle 241 may rotate to a point beyond the sweep trajectory ST.

The nozzle 241 may spray the cleaning liquid along the target trajectory TT on the surface of the substrate W. The target trajectory TT may be included in the surface of the substrate W. The target trajectory TT may draw an arc in a plan view. For example, the arc of the target trajectory TT may mean an arc of the circular surface of the substrate W in a plan view.

In some implementations of the present disclosure, the target trajectory TT may overlap the sweep trajectory ST in the third direction Z. That is, the target trajectory TT and the sweep trajectory ST may overlap each other and thus may draw the same arc in a plan view.

The target trajectory TT may include a plurality of target points TP. Each of the target points TP may correspond to each of the sweep points SP overlapping therewith in the vertical direction (e.g., the third direction Z). For example, a first target point TP1 and a second target point TP2 may respectively mean both opposing end points of the arc of the target trajectory TT. In addition, for example, a third target point TP3 may mean a center point of the arc of the target trajectory TT. That is, the first target point TP1 may overlap in the third direction Z and correspond to the first sweep point SP1, the second target point TP2 may overlap in the third direction Z and correspond to the second sweep point SP2, and the third target point TP3 may overlap in the third direction Z and correspond to the third sweep point SP3.

In some implementations of the present disclosure, a central axis C of the surface of the substrate W may be disposed between the target trajectory TT and the arm pillar (see 243 of FIG. 2). That is, at a time point at which the nozzle arm 242 passes through the third sweep point SP3, the central axis C of the substrate W may be screened with the nozzle arm 242 in a plan view.

In some implementations of the present disclosure, in a plan view, the cleaning liquid spraying direction ID of the nozzle 241 may coincide with the rotation direction TP_R1 of each of the target points TP corresponding to each of the sweep points SP while the nozzle 241 passes through each of the sweep points SP. That is, the cleaning liquid spray direction ID of the nozzle 241 may vary at each sweep point SP. This may be because the rotation directions TP_R1 of the target points TP corresponding to the sweep points SP are different from each other. For example, the rotation direction TP_R1 of each target point TP may be a direction orthogonal to a virtual line extending from the central axis C of the substrate W to each target point TP.

In some implementations of the present disclosure, while the nozzle arm 242 rotates along the sweep trajectory ST, an angle θ defined between the cleaning liquid ejection direction ID of the nozzle 241 and an extension direction 242D of the nozzle arm 242 may continuously change in a plan view. The change in the angle θ defined between the cleaning liquid spray direction ID of the nozzle 241 and the extension direction 242D of the nozzle arm 242 in a plan view will be described with reference to FIGS. 6-8.

Referring to FIGS. 6-8, in a plan view, an angle θ defined between the cleaning liquid spray direction ID of the nozzle 241 and the extension direction 242D of the nozzle arm 242 may increase and then decrease. For reference, in a plan view, the angle θ defined between the cleaning liquid spray direction ID of the nozzle 241 and the extension direction 242D of the nozzle arm 242 may mean an acute angle.

In FIG. 6, when the nozzle 241 rotates from the first sweep point SP 1 to the third sweep point SP3, the nozzle 241 may spray the cleaning liquid onto the target points TP arranged from the first target point TP1 to the third target point TP 3. When the nozzle 241 sprays the cleaning liquid on an “a” target point TPa between the first target point TP1 and the third target point TP3, an angle defined between the cleaning liquid spray direction ID of the nozzle 241 and the extension direction 242D of the nozzle arm 242 may be referred to as θa in a plan view.

For example, in a plan view, an angle θ1 defined between the cleaning liquid spray direction ID on the first target point TP1 and the extension direction 242D of the nozzle arm 242 may be smaller than the angle θa defined between the cleaning liquid spray direction ID on the “a” target point TPa and the extension direction 242D of the nozzle arm 242. For example, in a plan view, an angle θ3 between the cleaning liquid spray direction ID on the third target point TP3 and the extension direction 242D of the nozzle arm 242 may be greater than an angle θa defined between the cleaning liquid spray direction ID on the “a” target point TPa and the extension direction 242D of the nozzle arm 242.

That is, when the nozzle 241 rotates from the first sweep point SP1 to the third sweep point SP3, the angle θ defined between the cleaning liquid spray direction ID of the nozzle 241 and the extension direction 242D of the nozzle arm 242 may increase in a plan view.

In some implementations of the present disclosure, the angle θa defined between the cleaning liquid spray direction ID on the “a” target point TPa and the extension direction 242D of the nozzle arm 242 in a plan view may be a maximum when the “a” target point TPa is the third target point TP3. For example, in a plan view, the angle θ3 defined between the cleaning liquid spray direction ID on the third target point TP3 and the extension direction 242D of the nozzle arm 242 may be 90 degrees.

In FIG. 7, when the nozzle 241 rotates from the third sweep point SP3 to the second sweep point SP2, the nozzle 241 may spray the cleaning liquid onto the target points TP from the third target point TP3 to the second target point TP2. When the nozzle 241 sprays the cleaning liquid onto the “b” target point TPb between the third target point TP3 and the second target point TP2, an angle defined between the cleaning liquid spray direction ID of the nozzle 241 and the extension direction 242D of the nozzle arm 242 may be referred to as θb when viewed in a plan view.

For example, in a plan view, the angle θ3 defined between the cleaning liquid spray direction ID on the third target point TP3 and the extension direction 242D of the nozzle arm 242 may be greater than an angle θb defined between the cleaning liquid spray direction ID on a “b” target point TPb and the extension direction 242D of the nozzle arm 242. For example, in a plan view, the angle θ2 defined between the cleaning liquid spray direction ID on the second target point TP2 and the extension direction 242D of the nozzle arm 242 may be smaller than the angle θb defined between the cleaning liquid spray direction ID on the “b” target point TPb and the extension direction 242D of the nozzle arm 242.

That is, when the nozzle 241 rotates from the third sweep point SP3 to the second sweep point SP2, the angle θ defined between the cleaning liquid spray direction ID of the nozzle 241 and the extension direction 242D of the nozzle arm 242 may be reduced in a plan view.

In some implementations of the present disclosure, the angle θb defined between the cleaning liquid spray direction ID on the “b” target point TPb and the extension direction 242D of the nozzle arm 242 in a plan view may be a minimum when the “b” target point TPb is the second target point TP2.

In FIG. 8, a graph shows the angle θ defined between the cleaning liquid spray direction ID and the extension direction 242D of the nozzle arm 242 in a plan view based on each sweep point SP through which the nozzle 241 passes. As illustrated, in a plan view, the angle θ defined between the cleaning liquid spray direction ID and the extension direction 242D of the nozzle arm 242 may be minimum when the nozzle 241 passes through the first sweep point SP1 or the second sweep point SP2, and may be maximum when the nozzle passes through the third sweep point SP3. Accordingly, the graph may draw a parabolic shape.

In addition, while the nozzle 241 reciprocates along the sweep trajectory ST, the shape of the graph may be periodically repeated. As shown, θa may be greater than θb. However, this is merely an example.

When the substrate W is cleaned, the cleaning liquid highly splashes on the surface of the substrate in the substrate cleaning apparatus 200 because the rotation direction of the substrate W is different from the cleaning liquid injection direction ID of the nozzle 241.

In some implementations of the present disclosure, in a plan view, the cleaning liquid spray direction ID of the nozzle 241 and the rotation direction at the target point TP corresponding to the sweep point SP through which the nozzle 241 passes may coincide with each other. In addition, the controller (see 270 of FIG. 2) may be configured to control the angle θ defined between the cleaning liquid spray direction ID of the nozzle 241 and the extension direction 242D of the nozzle arm 242 to continuously change in a plan view. Accordingly, the substrate cleaning apparatus 200, which minimizes the splash of the cleaning liquid during the cleaning process of the substrate W, and the substrate treating system including the same may be provided.

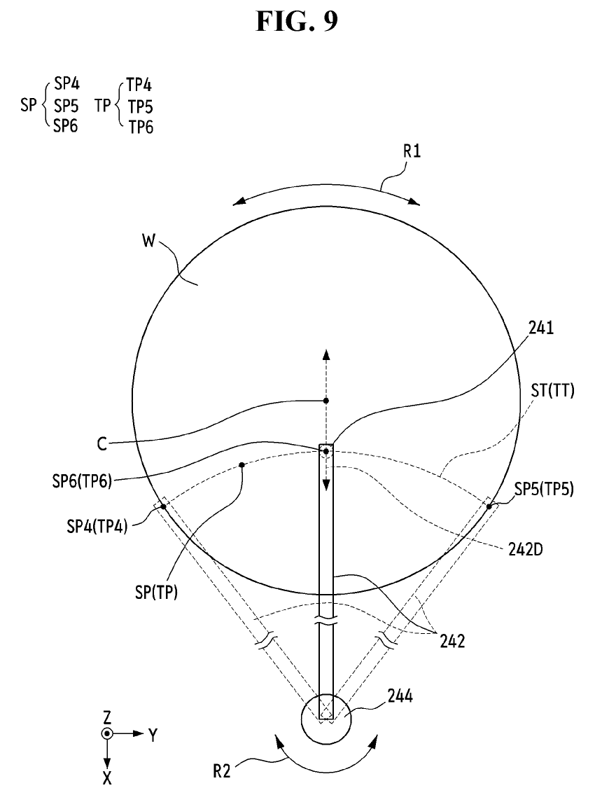

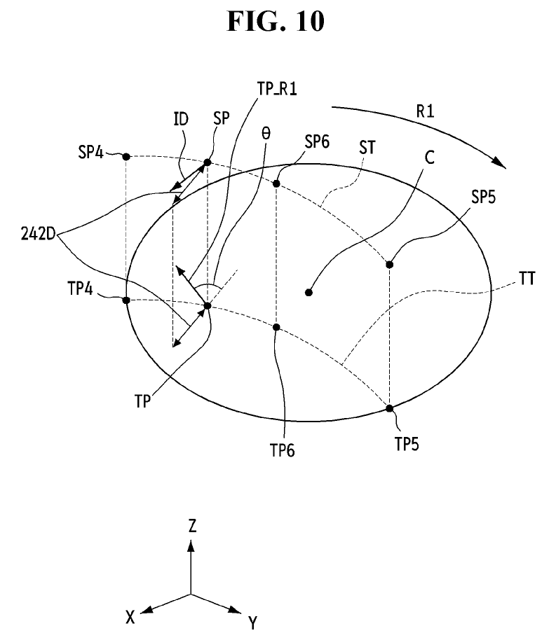

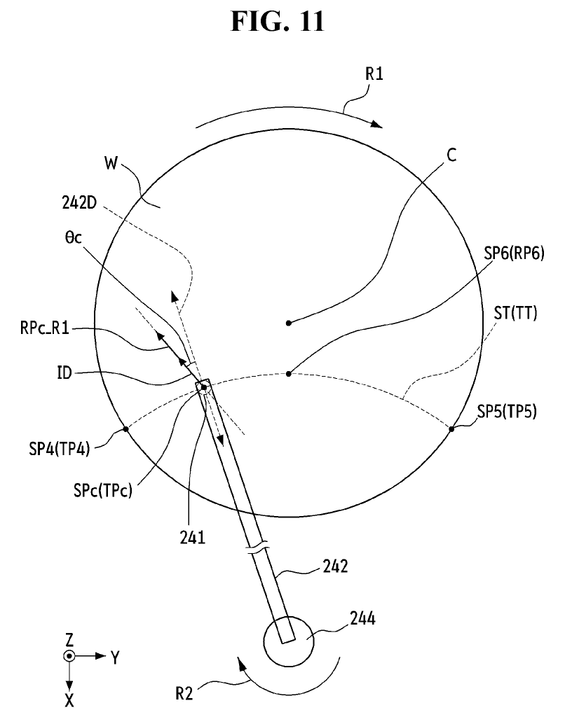

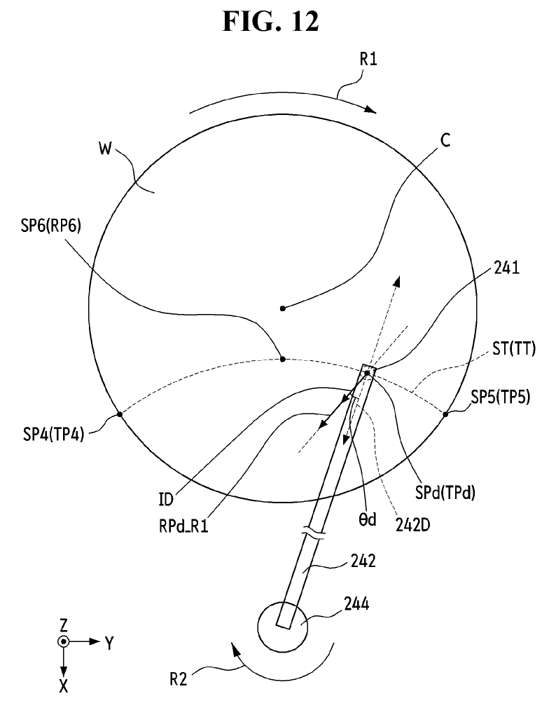

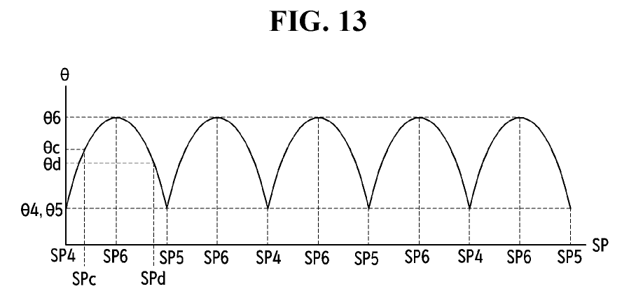

FIG. 9 is a plan view for illustrating that the nozzle arm rotates on a substrate according to some implementations of the present disclosure. FIG. 10 is a schematic perspective view for illustrating that the nozzle arm rotates on a substrate according to some implementations of the present disclosure. FIGS. 11 and 12 are schematic plan views illustrating that the nozzle sprays a cleaning liquid onto a substrate according to some implementations of the present disclosure. FIG. 13 is a graph illustrating an angle defined between a nozzle arm and a cleaning liquid spray direction of a nozzle based on a position of the nozzle according to some implementations of the present disclosure. Contents duplicate with or similar to those described above with reference to FIGS. 1-8 will be briefly described or descriptions thereof will be omitted.

Referring to FIGS. 9-13, in some implementations of the present disclosure, a sixth target point TP6 may be disposed between the central axis C of the surface of the substrate W and the arm pillar (see 243 in FIG. 2).

That is, the sweep trajectory ST may be disposed between the central axis C of the surface of the substrate W and the arm pillar 243. When the nozzle arm 242 passes through the sixth sweep point SP6, the central axis C of the substrate W may be spaced apart from the nozzle arm 242 in a plan view.

In some implementations of the present disclosure, since each of a fourth sweep point SP4, a fifth sweep point SP5, and a sixth sweep point SP6 corresponds to each of the first sweep point SP1, the second sweep point SP2, and the third sweep point SP3 described above with reference to FIGS. 4-8, a detailed description thereof will be omitted. This is equally applied to the fourth target point TP4, the fifth target point TP5, and the sixth target point TP6.

For example, in a plan view, the cleaning liquid spray direction ID of the nozzle 241 and the rotation direction at the target point TP corresponding to the sweep point SP through which the nozzle 241 passes may coincide with each other. In addition, the controller (see 270 of FIG. 2) may be configured to control the angle θ defined between the cleaning liquid spray direction ID of the nozzle 241 and the extension direction 242D of the nozzle arm 242 to continuously change in a plan view. Accordingly, the substrate cleaning apparatus 200 may be configured to minimize the splash of the cleaning liquid during the cleaning process of the substrate W.

In addition, for example, an angle θ defined between the cleaning liquid spray direction ID and the extension direction 242D of the nozzle arm 242 in a plan view may be minimum when the nozzle 241 passes through the fourth sweep point SP4 or the fifth sweep point SP5, and may be maximum when the nozzle passes through the sixth sweep point SP6. Accordingly, in FIG. 13, when the angle θ defined between the cleaning liquid spray direction ID and the extension direction 242D of the nozzle arm 242 at each sweep point SP through which the nozzle 241 passes is graphically illustrated, a parabolic shape may repeatedly appear.

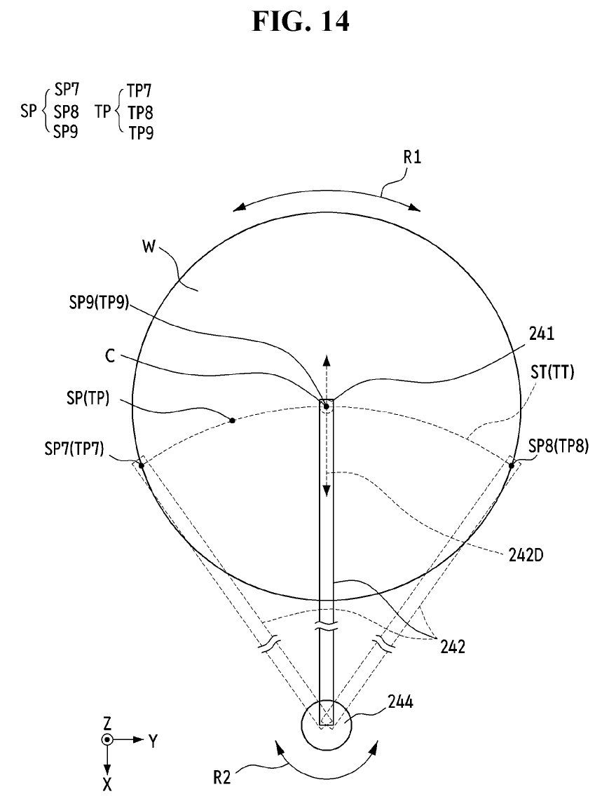

FIG. 14 is a plan view for illustrating that a nozzle arm rotates on a substrate according to some implementations of the present disclosure. Contents duplicate or similar to those described with reference to FIGS. 1-8 will be briefly described or the descriptions thereof will be omitted.

Referring to FIG. 14, a ninth target point TP9 may overlap the central axis C of the surface of the substrate W.

In some implementations of the present disclosure, the central axis C of the surface of the substrate W may pass through the ninth target point TP9. That is, the nozzle 241 may spray the cleaning liquid to the center of the substrate W.

In some implementations of the present disclosure, since each of the seventh sweep point SP7, the eighth sweep point SP8, and the ninth sweep point SP9 corresponds to each of the first sweep point SP1, the second sweep point SP2, and the third sweep point SP3 as described above with reference to FIGS. 4-8, a detailed description thereof will be omitted. This is equally applied to the seventh target point TP7, the eighth target point TP8, and the ninth target point TP9.

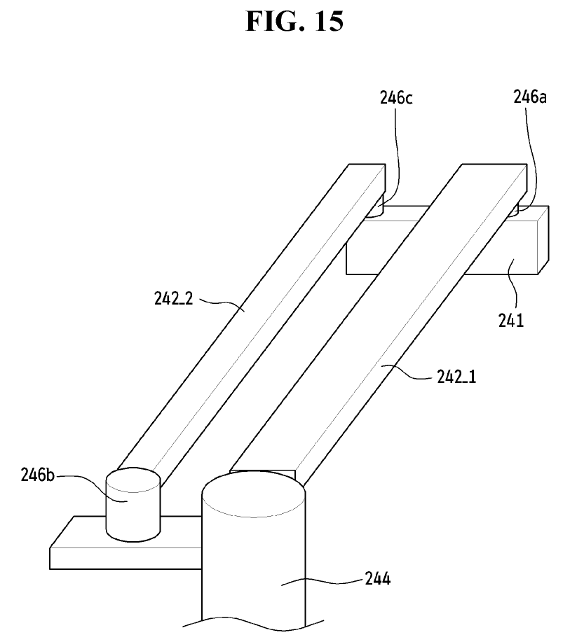

FIG. 15 is a perspective view for illustrating a nozzle according to some implementations of the present disclosure. Contents duplicate or similar to those described with reference to FIGS. 1-8 will be briefly described or the descriptions thereof will be omitted.

Referring to FIG. 15, the substrate cleaning apparatus (see 200 of FIG. 2) according to some implementations may include a first sub-nozzle arm 242_1, a second sub-nozzle arm 242_2, and first to third hinge shafts 246a, 246b, and 246c.

In some implementations of the present disclosure, the nozzle arm 242 may include the first sub-nozzle arm 242_1 and the second sub-nozzle arm 242_2. The first sub-nozzle arm 242_1 may contact the rotation driver 244. The second sub-nozzle arm 242_2 may be connected to the rotation driver 244 via the second hinge shaft 246b.

The first sub-nozzle arm 242_1 may rotate in a horizontal direction (e.g., the R2 direction in FIG. 2) under the operation of the rotation driver 244. The first sub-nozzle arm 242_1 may be connected to the nozzle 241 via the first hinge shaft 246a. The first sub-nozzle arm 242_1 may rotate the nozzle 241 via the first hinge shaft 246a. That is, via the first sub-nozzle arm 242_1, the nozzle 241 may rotate along the sweep trajectory (e.g., refer to ST of FIG. 4).

The second sub-nozzle arm 242_2 may be connected to the nozzle 241 via the third hinge shaft 246c. In some implementations of the present disclosure, the second sub-nozzle arm 242_2 may rotate along the circumference of the rotation driver 244 via the second hinge shaft 246b. The second sub-nozzle arm 242_2 may transmit, to the nozzle 241, a force that rotates the nozzle along the circumference of the rotation driver 244 via the third hinge shaft 246c. Accordingly, an angle defined between the extension direction of the nozzle 241 and the extension direction of the first sub-nozzle arm 242_1 may vary.

In some implementations of the present disclosure, in a plan view, the spraying direction of the nozzle 241 may be perpendicular to the extending direction of the nozzle 241. In this regard, the extension direction of the nozzle 241 may mean an extension direction of the long side of the nozzle 241. When the angle defined between the extension direction of the nozzle 241 and the extension direction of the first sub-nozzle arm 242_1 varies, the direction in which the cleaning liquid is sprayed onto the target point TP on the surface of the substrate W may also vary accordingly. That is, via the first sub-nozzle arm 242_1, the second sub-nozzle arm 242_2, and the first to third hinge shafts 246a, 246b, and 246c, the cleaning liquid spray direction of the nozzle 241 may coincide with the rotation direction at the target point TP corresponding to the sweep point SP through which the nozzle 241 passes, in a plan view. The controller (see 270 of FIG. 2) may be configured to control each of the first sub-nozzle arm 242_1, the second sub-nozzle arm 242_2, and the first to third hinge shafts 246a, 246b, and 246c.

Although implementations of the present disclosure have been described with reference to the accompanying drawings, the present disclosure is not limited to the above implementations, but may be realized in various different forms. A person skilled in the art may appreciate that the present disclosure may be practiced in other concrete forms without changing the technical spirit or essential characteristics of the present disclosure. Therefore, it should be appreciated that the implementations as described above is not restrictive but illustrative in all respects.

What is claimed is:

1. A substrate cleaning apparatus comprising:
a substrate holder configured to support a substrate;
a spin pillar connected to the substrate holder and configured to rotate the substrate; and
a cleaning liquid supply structure configured to spray a cleaning liquid onto a surface of the substrate,
wherein the cleaning liquid supply structure comprises:
a nozzle arm having a first end rotating along a sweep trajectory over the surface of the substrate, and
a nozzle coupled to the first end of the nozzle arm and configured to spray the cleaning liquid along a target trajectory on the surface of the substrate,
wherein the sweep trajectory comprises a plurality of sweep points,
wherein the target trajectory comprises a plurality of target points corresponding to and overlapping the plurality of sweep points in a vertical direction, and
wherein the nozzle is configured to, while the nozzle passes through each of the plurality of sweep points, spray the cleaning liquid in a spraying direction that coincides with a rotational direction of each of the plurality of target points corresponding to each of the plurality of sweep points.

2. The substrate cleaning apparatus of claim 1, wherein, based on the nozzle arm being rotated along the sweep trajectory, an angle is defined between the spraying direction and an extension direction of the nozzle arm and continuously changes.

3. The substrate cleaning apparatus of claim 1, wherein the plurality of target points comprise a first target point, a second target point, and a third target point,
wherein the target trajectory extends along an arc on the surface of the substrate,
wherein the first target point and the second target point are at a first end point of the arc and a second end point of the arc, respectively, the first end point and the second end point being opposing end points of the arc, and
wherein the third target point is at a center point of the arc.

4. The substrate cleaning apparatus of claim 3, wherein, based on the nozzle spraying the cleaning liquid along a portion of the arc from the first target point to the third target point as the nozzle rotates along the sweep trajectory, an angle is defined between the spraying direction and an extension direction of the nozzle arm and increases.

5. The substrate cleaning apparatus of claim 3, wherein, based on the nozzle spraying the cleaning liquid along a portion of the arc from the third target point to the second target point as the nozzle rotates along the sweep trajectory, an angle is defined between the spraying direction and an extension direction of the nozzle arm and decreases.

6. The substrate cleaning apparatus of claim 3, wherein, based on the nozzle spraying the cleaning liquid onto the third target point, an angle is defined between the spraying direction and an extension direction of the nozzle arm and reaches a maximum value.

7. The substrate cleaning apparatus of claim 3, wherein the third target point corresponds to a center point of the surface of the substrate.

8. The substrate cleaning apparatus of claim 1, comprising a controller configured to control each of the cleaning liquid supply structure and the spin pillar.

9. The substrate cleaning apparatus of claim 8, wherein the controller is configured to control the nozzle arm to reciprocate along the sweep trajectory.

10. The substrate cleaning apparatus of claim 8, wherein the controller is configured to control the nozzle such that the spraying direction coincides with the rotational direction.

11. The substrate cleaning apparatus of claim 1, wherein the cleaning liquid supply structure comprises an arm pillar coupled to a second end of the nozzle arm and configured to rotate the nozzle arm.

12. The substrate cleaning apparatus of claim 11, wherein the target trajectory is between a center of the surface of the substrate and the arm pillar.

13. The substrate cleaning apparatus of claim 11, wherein a center of the surface of the substrate is between the target trajectory and the arm pillar.

14. A substrate cleaning apparatus comprising:
a housing;
a substrate holder in the housing and configured to support a substrate;
a spin pillar connected to the substrate holder and configured to rotate the substrate;
a door on a side wall of the housing, wherein the housing is configured to, through the door, receive the substrate as input or withdraw the substrate to an outside of the housing;
a fan filter on an upper surface of the housing and configured to control an airflow inside the housing;
a cleaning liquid supply structure configured to spray a cleaning liquid onto a surface of the substrate; and
a controller configured to control each of the cleaning liquid supply structure and the spin pillar,
wherein the cleaning liquid supply structure comprises:
an arm pillar extending parallel to a central axis of the substrate, and
a nozzle arm having a first end connected to the arm pillar and a second end configured to rotate along a sweep trajectory over the surface of the substrate; and
a nozzle coupled to the second end of the nozzle arm and configured to spray the cleaning liquid along a target trajectory on the surface of the substrate, and
wherein the controller is configured to control a spraying direction of the nozzle to continuously vary while the nozzle travels along the sweep trajectory.

15. The substrate cleaning apparatus of claim 14, wherein the sweep trajectory comprises a plurality of sweep points,
wherein the target trajectory comprises a plurality of target points corresponding to and overlapping the plurality of sweep points in a vertical direction, and
wherein, the controller is configured to, while the nozzle passes through each of the plurality of sweep points, control the spraying direction of the nozzle to coincide with a rotational direction of each of the plurality of target points corresponding to each of the plurality of sweep points.

16. The substrate cleaning apparatus of claim 14, wherein the sweep trajectory comprises a plurality of sweep points,
wherein the target trajectory comprises a plurality of target points corresponding to and overlapping the plurality of sweep points in a vertical direction, and
wherein the plurality of target points comprise a first target point, a second target point, and a third target point,
wherein the target trajectory extends along an arc on the surface of the substrate,
wherein the first target point and the second target point are at a first end point of the arc and a second end point of the arc, respectively, the first end point and the second end point being opposing end points of the arc, and
wherein the third target point is at a center point of the arc.

17. The substrate cleaning apparatus of claim 16, wherein, based on the nozzle spraying the cleaning liquid along a portion of the arc from the first target point to the third target point as the nozzle rotates along the sweep trajectory, an angle is defined between the spraying direction and an extension direction of the nozzle arm and increases.

18. The substrate cleaning apparatus of claim 16,
wherein, based on the nozzle spraying the cleaning liquid along a portion of the arc from the third target point to the second target point as the nozzle rotates along the sweep trajectory, an angle is defined between the spraying direction and an extension direction of the nozzle arm and decreases.

19. A substrate treating system for treating a substrate, the system comprising:
a process-treating apparatus configured to process the substrate; and
a substrate cleaning apparatus for cleaning the substrate after the process-treating apparatus has processed the substrate,
wherein the substrate cleaning apparatus comprises:
a substrate holder configured to support the substrate,
a spin pillar connected to the substrate holder and configured to rotate the substrate, and
a cleaning liquid supply structure configured to spray a cleaning liquid onto a surface of the substrate,
wherein the cleaning liquid supply structure comprises:
a nozzle arm having a first end rotating along a sweep trajectory over the surface of the substrate, and
a nozzle coupled to the first end of the nozzle arm and configured to spray the cleaning liquid along a target trajectory on the surface of the substrate,
wherein the sweep trajectory comprises a plurality of sweep points,
wherein the target trajectory comprises a plurality of target points corresponding to and overlapping the plurality of sweep points in a vertical direction,
wherein the nozzle is configured to, while the nozzle passes through each of the plurality of sweep points, spray the cleaning liquid in a spraying direction that coincides with a rotational direction of each of the plurality of target points corresponding to each of the plurality of sweep points.

20. The substrate treating system of claim 19, wherein, based on the nozzle arm being rotated along the sweep trajectory, an angle is defined between the spraying direction and an extension direction of the nozzle arm and continuously changes.
